(19) United States
(12) Patent Application Publication
(10) Pub. No.: US 2025/0053851 A1
(43) Pub. Date: Feb. 13, 2025

(54) RESERVOIR COMPUTING BASED ON FERROMAGNETIC FILMS WITH POINT DEFORMATIONS

(71) Applicant: International Business Machines Corporation, Armonk, NY (US)

(72) Inventors: Rolf Allenspach, Adliswil (CH); Andreas Bischof, Männedorf (CH)

(21) Appl. No.: 18/231,619

(22) Filed: Aug. 8, 2023

(51) Int. Cl. G06N 20/00

(52) U.S. Cl. CPC G06N 20/00

(57) ABSTRACT

The invention is notably directed to a physical reservoir for a magnetic reservoir computing apparatus. The physical reservoir includes a ferromagnetic film, which comprises a two-dimensional arrangement of point deformations. The point deformations are dimensioned to act as pinning sites for magnetic domains of the ferromagnetic film. The invention further concerns a magnetic reservoir computing apparatus comprising such a physical reservoir, as well as methods of operating and fabricating such a reservoir computing apparatus. The proposed approach results in a low-power-consumption physical reservoir, which is easy to fabricate.

### STATEMENT REGARDING FEDERALLY SPONSORED RESEARCH OR DEVELOPMENT

The project leading to this application has received funding from the European Union's Horizon 2020 research and innovation program under FET-Open SpinENGINE project, grant number 861618.

### TECHNICAL FIELD

The invention relates in general to the field of reservoir computing. In particular, it is directed to a physical reservoir for a magnetic reservoir computing apparatus, as well as a magnetic reservoir computing apparatus comprising a physical reservoir, a method of operating a reservoir computing apparatus, and a method of fabricating a reservoir computing apparatus.

### BACKGROUND

Reservoir computing refers to machine learning computational techniques, in which input signals are fed into a fixed, random dynamical system (the reservoir). Dynamics of the reservoir map inputs onto a higher dimensional space. A simple readout mechanism (e.g., a single output layer) is used to read the state of the reservoir and map this state onto outputs. The training is performed only at the readout stage, whereas the reservoir is fixed. This approach exploits the computational power enabled by the dynamics of the fixed reservoir and reduces the training computational cost.

The reservoirs can be virtual (e.g., a randomly generated network) or physical. Physical reservoirs typically exploit the non-linearity of certain natural systems. Various types of physical reservoirs have been proposed, including electronic, photonic, mechanical, chemical, and liquid-state reservoirs.

More recently, magnetic reservoirs have been proposed, which rely on nanomagnets/spintronic oscillators. A challenge with magnetic reservoirs is to achieve a low-power-consumption physical reservoir, which is nonetheless easy to manufacture.

### SUMMARY

According to a first aspect, the present invention is embodied as a physical reservoir for a magnetic reservoir computing apparatus. The physical reservoir includes a ferromagnetic film, which comprises a two-dimensional arrangement of point deformations. The point deformations are dimensioned to act as pinning sites for magnetic domains of the ferromagnetic film.

For instance, the point deformations can be punctures or point protrusions. Preferred is to rely on punctures, as these are easier to obtain than point protrusions. Patterning point deformations in the ferromagnetic film make it possible to obtain a robust, highly non-linear, and stochastic response of the ferromagnetic film to external stimuli. Thanks to such point deformations, the physical reservoir is nonlinear, stochastic, and displays fading memory. Moreover, single-point deformations are much easier to obtain than previously proposed nanomagnet/spintronic oscillators. What is more, point deformations require less power to set the state of the reservoir. Thus, the present approach can adequately be used for reservoir computing.

The structural properties of the film can be optimized to lower the power consumption of the physical reservoir. In that respect, in embodiments, the average first-neighbor distance between the punctures is of between 0.2 μm and 5.0 μm, preferably between 0.5 μm and 3.0 μm. Any first-neighbor distance between the punctures is measured parallel to a main surface of the ferromagnetic film. The average diameter of the punctures is of between 50 nm and 500 nm, preferably between 70 nm and 380 nm, it being noted that the average diameter of the punctures is smaller than said average first-neighbor distance. Any diameter of the punctures is again measured parallel to the main surface of the ferromagnetic film.

In embodiments, the thickness of the ferromagnetic film is of between 2 nm and 50 nm. Preferably, this thickness is of between 5 nm and 20 nm. In embodiments, a length of each edge of the ferromagnetic film is of between 20 μm and 200 μm. The physical reservoir may typically include a substrate supporting the ferromagnetic film.

In embodiments, said two-dimensional arrangement forms at least one lattice of the point deformations, e.g., a square lattice. A lattice of point deformations is easily obtained, e.g., using a nanoimprint or nanostencil techniques. Further, any or each of the lattices involved may be formed as an antidot lattice. Still, the non-linearity and stochasticity of the reservoir response can be enhanced by introducing “defects” in the two-dimensional arrangement of point deformations. For example, the two-dimensional arrangement may form at least two lattices of point deformations, having distinct lattice parameters, in distinct areas of the ferromagnetic film.

In some embodiments, and preferably, the ferromagnetic film comprises one or more elements selected from the group comprising transition metal elements. Preferably, the ferromagnetic film comprises FeₓNi₁₀₀₋ₓ, where 20≤x≤60. The composition can be tuned to lower the saturation magnetization and, in turn, the power consumption of the reservoir. For example, the film may comprise Fe₅₅Ni₄₅.

According to another aspect, the invention is embodied as a magnetic reservoir computing apparatus. The apparatus comprises a physical reservoir, a driving system, and a readout unit. Consistently with the previous aspect, the physical reservoir comprises a ferromagnetic film with a two-dimensional arrangement of point deformations, which are dimensioned to act as pinning sites for magnetic domains of the ferromagnetic film. In addition, the driving system is configured to saturate the ferromagnetic film and couple input signals into the ferromagnetic film to set a magnetic state of the ferromagnetic film. The readout unit is operatively connected to the physical reservoir to read out output signals from the ferromagnetic film.

In some embodiments, and preferably, the driving system includes two or more coils, which are configured to apply a rotating magnetic field, in-plane with the ferromagnetic film, whereby the driving system is adapted to couple input signals into the physical reservoir.

In some embodiments, the driving system is operatively connected to the ferromagnetic film to apply one or more electric current signals to the ferromagnetic film. For instance, the physical reservoir may include an arrangement of electrical conductors connecting the driving system to multiple locations in the ferromagnetic film. In that case, the driving system is configured to apply electric current signals to the ferromagnetic film through the electrical conductors to locally generate magnetic fields in the ferromagnetic film, in-plane with the ferromagnetic film.

The driving system may, for instance, be operatively connected to apply said electric current signals to the ferromagnetic film to move domain walls in the ferromagnetic film according to one of a spin-transfer torque mechanism and a spin-orbit torque mechanism.

In some embodiments, and preferably, the apparatus further comprises a processing unit, which is connected to the readout unit and is configured to further process signals from the reservoir.

According to another aspect, the invention is embodied as a method of operating a reservoir computing apparatus. The method comprises setting a magnetic state of the physical reservoir. Again, the physical reservoir comprises a ferromagnetic film with a two-dimensional arrangement of point deformations, which are dimensioned to act as pinning sites for magnetic domains of the ferromagnetic film. The magnetic state is set by saturating the ferromagnetic film and coupling input signals into the physical reservoir to generate one or more magnetic fields in-plane with the ferromagnetic film. In embodiments, the method further comprises reading out output signals from the physical reservoir and processing the output signals to obtain one or more inference results, such as classification results.

According to a final aspect, the invention is embodied as a method of fabricating a reservoir computing apparatus. The method revolves around patterning a ferromagnetic film of a physical reservoir. In addition, the method comprises connecting the physical reservoir (which eventually contains the ferromagnetic film) with one or more additional components of the reservoir computing apparatus. Consistently with previous aspects of the invention, the ferromagnetic film is patterned to obtain a two-dimensional arrangement of point deformations in the ferromagnetic film, where the point deformations are dimensioned to act as pinning sites for magnetic domains of the ferromagnetic film, so as to obtain the physical reservoir.

In some embodiments, the ferromagnetic film is patterned by nanoimprint lithography. In other embodiments, the ferromagnetic film is patterned using a nanostencil technique.

### BRIEF DESCRIPTION OF THE DRAWINGS

These and other objects, features and advantages of the present invention will become apparent from the following detailed description of illustrative embodiments thereof, which is to be read in connection with the accompanying drawings. The illustrations are for clarity in facilitating one skilled in the art in understanding the invention in conjunction with the detailed description. In the drawings:

FIG. 1A is a diagram of selected components of a reservoir computing apparatus according to embodiments of the present invention, illustrating how input data are mapped onto a physical reservoir and read out to produce a classification result. The physical reservoir includes a ferromagnetic film such as shown in FIGS. 3A-4E;

FIG. 1B is a high-level diagram of the reservoir computing apparatus of FIG. 1A, illustrating operative connections between components of the apparatus;

FIG. 2 is a diagram of an in-memory compute device having a crossbar array structure, which can be used in output of a reservoir computing apparatus as shown in FIGS. 1A and 2A, according to embodiments of the present invention;

FIG. 3A is an exploded view of a layer structure of a physical reservoir, involving a ferromagnetic film patterned to include a two-dimensional arrangement of point deformations (e.g., punctures), according to embodiments of the present invention;

FIG. 3B is a top view of the ferromagnetic film of the physical reservoir of FIG. 3A;

FIG. 3C is a 3D view of a portion of the ferromagnetic film of the physical reservoir of FIG. 3A, showing electrical conductors (also visible in FIG. 3A) patterned on opposite sides of the film, according to embodiments of the present invention;

FIG. 4A is a first 2D cross-sectional view of a portion of a ferromagnetic film, which illustrates how a ferromagnetic film can be locally processed to form point deformations according to embodiments of the present invention. The point deformations are dimensioned to act as pinning sites for magnetic domains of the ferromagnetic film.

FIG. 4B is a second 2D cross-sectional view of a portion of a ferromagnetic film, which illustrates how a ferromagnetic film can be locally processed to form point deformations according to embodiments of the present invention. The point deformations are dimensioned to act as pinning sites for magnetic domains of the ferromagnetic film.

FIG. 4C is a third 2D cross-sectional view of a portion of a ferromagnetic film, which illustrates how a ferromagnetic film can be locally processed to form point deformations according to embodiments of the present invention. The point deformations are dimensioned to act as pinning sites for magnetic domains of the ferromagnetic film.

FIG. 4D is a fourth 2D cross-sectional view of a portion of a ferromagnetic film, which illustrates how a ferromagnetic film can be locally processed to form point deformations according to embodiments of the present invention. The point deformations are dimensioned to act as pinning sites for magnetic domains of the ferromagnetic film.

FIG. 4E is a fifth 2D cross-sectional view of a portion of a ferromagnetic film, which illustrates how a ferromagnetic film can be locally processed to form point deformations according to embodiments of the present invention. The point deformations are dimensioned to act as pinning sites for magnetic domains of the ferromagnetic film. In the examples of FIGS. 4A-4D, the point deformations are formed as punctures, whereas they are formed as protrusions in the example of FIG. 4E;

FIG. 5A is a map of secondary electrons of a permalloy Fe₅₅Ni₄₅ antidot lattice obtained by “drilling” the holes with a focused ion beam tool, according to embodiments of the present invention. A thresholding function was applied to the topographic map of FIG. 5A, for the sake of depiction;

FIG. 5B shows the corresponding in-plane magnetization distribution with respect to FIG. 5A, where the in-plane magnetization direction is represented by arrows.

FIG. 6 is a graph representing the anisotropic magnetoresistance (AMR) of a ferromagnetic film (such as shown in FIG. 5A) as a function of an applied magnetic field, illustrating the magnetic response of the ferromagnetic film to a cycling magnetic field, for various lattice constants;

FIG. 7 is a top view of a ferromagnetic film of a physical reservoir, similar to FIG. 3B, except that the film of FIG. 7 now includes distinct lattices of point deformations (e.g., punctures) in distinct areas of the film, where the lattices have distinct lattice parameters, according to embodiments of the present invention;

FIG. 8 is a flowchart illustrating high-level steps of a method of setting a magnetic state of a ferromagnetic film according to embodiments of the present invention.

FIG. 9 is a flowchart illustrating high-level steps of a method of operating a reservoir computing apparatus according to embodiments of the present invention.

FIG. 10 is a flowchart illustrating high-level steps of a method of fabricating a ferromagnetic film of a physical reservoir of a computing apparatus, according to embodiments of the present invention.

The accompanying drawings show simplified representations of apparatuses, devices, or parts thereof, as involved in embodiments. Technical features depicted in the drawings are not necessarily to scale. Similar or functionally similar elements in the figures have been allocated the same numeral references, unless otherwise indicated.

Physical reservoirs, magnetic reservoir computing apparatuses, and methods embodying the present invention will now be described, by way of non-limiting examples.

### DETAILED DESCRIPTION

The following description is structured as follows. General embodiments and high-level variants are described in section 1. Section 2 includes a detailed description of the appended drawings. All references Sn refer to methods steps of the flowcharts of FIGS. 8-10, while numeral references pertain to devices, components, and concepts, involved in embodiments of the present invention.

### 1. General Embodiments and High-Level Variants

This section addresses a physical reservoir (section 1.1), a magnetic reservoir computing apparatus (section 1.2), a method of operating reservoir computing apparatuses (section 1.3), and fabrication methods (section 1.4), all according to embodiments.

### 1.1. Physical Reservoir

### 1.1.1. Main Features

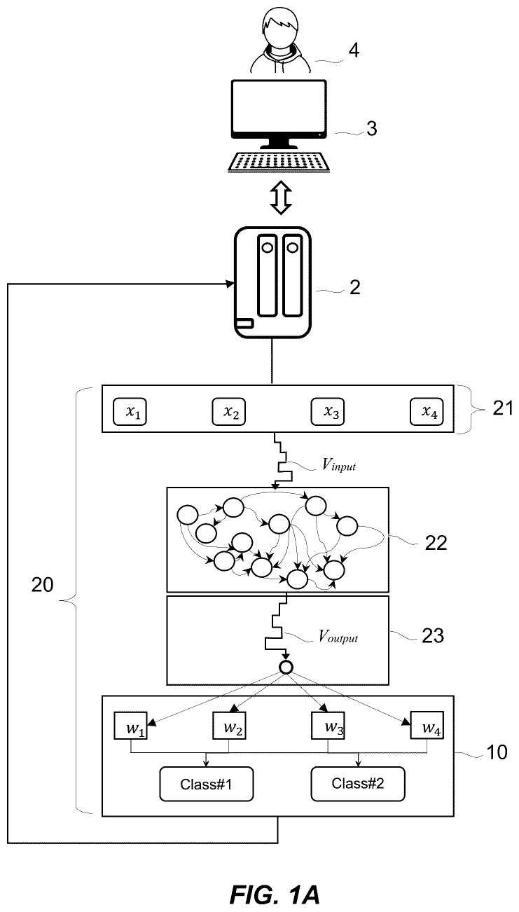

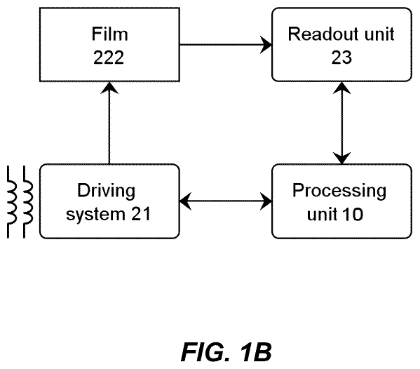

A first aspect of the invention is now described in detail, in reference to FIGS. 1A, 1B, 3A, 3B, and 4A to 5B. This aspect concerns a physical reservoir 22 for a magnetic reservoir computing apparatus 20. According to the embodiments of the invention, the physical reservoir 22 includes a ferromagnetic film 222, where the film comprises a two-dimensional (2D) arrangement of point deformations 225, such as punctures. The point deformations 225 are dimensioned to act as pinning sites for magnetic domains of the ferromagnetic film 222.

### 1.1.2. Comments and Definitions

As noted in the background section, reservoir computing (RC) is a computational framework that exploits non-linear dynamics of the reservoir. In the present case, the reservoir is a physical reservoir, which includes a ferromagnetic film (also referred to as a “film”) containing a ferromagnetic material. As with RC in general, the underlying idea is to map input signals into the high-dimensional computational space embodied by the reservoir. The latter is a fixed, non-linear system, which embodies a reservoir network, as schematically depicted in FIG. 1A. The physical reservoir 22 is meant to be used in an apparatus 20 that uses a simple readout mechanism. Such an apparatus 20 concerns another aspect of the invention, which is described later in detail.

The readout unit 23 includes or is connected to processing unit 10. The processing unit 10 implements a computational model that can be trained to read the state of the reservoir and learn how to map this state to desired outputs (e.g., labels), as in a usual supervised setting. For inferencing purposes, after the input signal is fed into the reservoir (which remains fixed), the readout unit 23 reads the state of the reservoir and the processing unit 10 maps it to outputs in accordance with the learned parameters. A key advantage is that the training is performed only at the readout level, while the reservoir dynamics remain fixed. That is, as with RC in general, the present approach takes advantage of the inherent computational power of the reservoir. The main difference with prior RC approaches is that, in the present case, the reservoir comprises a patterned ferromagnetic film 222, as described in detail below.

The ferromagnetic film 222 includes a 2D arrangement of point deformations 225, such as punctures. The 2D arrangement of point deformations 225 may advantageously form a lattice, i.e., an ordered arrangement (a 2D array) of the deformations. In some embodiments, the 2D arrangement forms a disordered (or a non-constant) arrangement of point deformations 225. The 2D arrangement of deformations may, for instance, form a polycrystalline-like arrangement of point deformations 225. That is, the 2D arrangement may combine several lattices having distinct lattice steps and/or distinct symmetry. The lattice(s) may further include local lattice defects, on purpose, to create specific nodes in the reservoir network embodied by the film 222. Using lattices of deformations make it easier to pattern the ferromagnetic film 222.

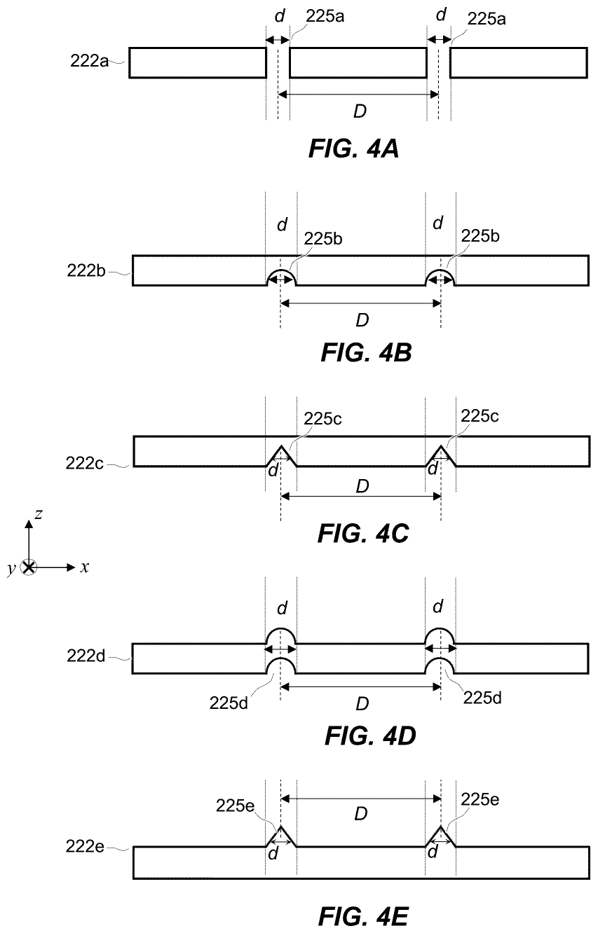

In embodiments, the point deformations 225 are obtained as point protrusions 225e, as illustrated in FIG. 4E. In some embodiments, and preferably, the point deformations 225 are obtained as punctures 225a, 225b, 225c, 225d, as illustrated in FIGS. 4A-4D. In all cases, the point deformations 225 are single-point, local, and compact, deformation of the ferromagnetic film, whereby a small amount of material is locally removed, displaced, or added, so as to result in a recess, a depression, a hole, or a protrusion. In practice, punctures 225a-d are easier to obtain than point protrusions 225e. A puncture is a small hole, and can be, for example, a through hole 225a, as in FIG. 4A, a blind hole or a depression 225b-d, as in FIGS. 4B-4D. A puncture on one side of the film 222d may further result in a rippling deformation, see FIG. 4D.

In general, the shape of the punctures can be similar to the deformation that would be obtained by drilling, boring, punching or perforating (at least partly), or otherwise deforming, a sheet-like work piece (e.g., a metal sheet) in a single point, except that the dimensions of the present punctures are much smaller, as exemplified below. That is, in the present case, nanoscopic or microscopic deformations are obtained, e.g., by means of a nanoimprint or nanostencil techniques. As used herein, the point deformations 225 are generally referred to by numeral reference 225, except in FIGS. 4A-4E and the supporting description, where the different types of deformations shown are referred to by references 225a-e. Similarly, the corresponding ferromagnetic films 222a-e are generally referred to herein by numeral reference 222.

Unlike nanorings or other similar processed shapes, point deformations 225 as contemplated herein do not require complex lithographic patterning steps. They can be obtained by simple processing steps. In particular, punctures can be obtained by a single process step, e.g., thanks to nanostencil or nanoimprint lithographic techniques. The resulting shapes of the deformations differ, in terms of shapes and compactness, from ring-like deformations as proposed in the prior art. That is, and as their name suggests, point deformations 225 form more compact recesses and/or protrusions.

Ideally, any in-plane section (i.e., a section parallel to a main surface of the film) of the point deformation essentially forms a compact region that is bounded at the periphery by a simple closed curve. This ideal section may, for instance, draw a circle enclosing a hollow region as in FIGS. 4A, 4B or a simple polygon, i.e., a polygon that does not intersect itself and has no holes. The surface of this section is closed at the periphery by a boundary formed by the peripheral edge of the ferromagnetic film 222a, 222b. The in-plane section of the point deformations 225 is not necessarily constant along the axis z (i.e., the out-of-plane axis), perpendicular to the main surface (x, y), this depending on the process used to obtain the deformations. Thus, the shape of the punctures 225a-225d will ideally be an essentially convex object, e.g., cylindrical as in FIG. 4A, partly spherical as in FIG. 4B, or pyramidal as in FIG. 4C. The local deformations may cause the film 222d to bulge (or otherwise create a protrusion) on the side of the film opposite to the puncture 225d, as illustrated in FIG. 4D. Protrusions 225e as shown in FIG. 4E are typically more difficult to obtain than punctures 225a-d, inasmuch as they require depositing material on top of the film.

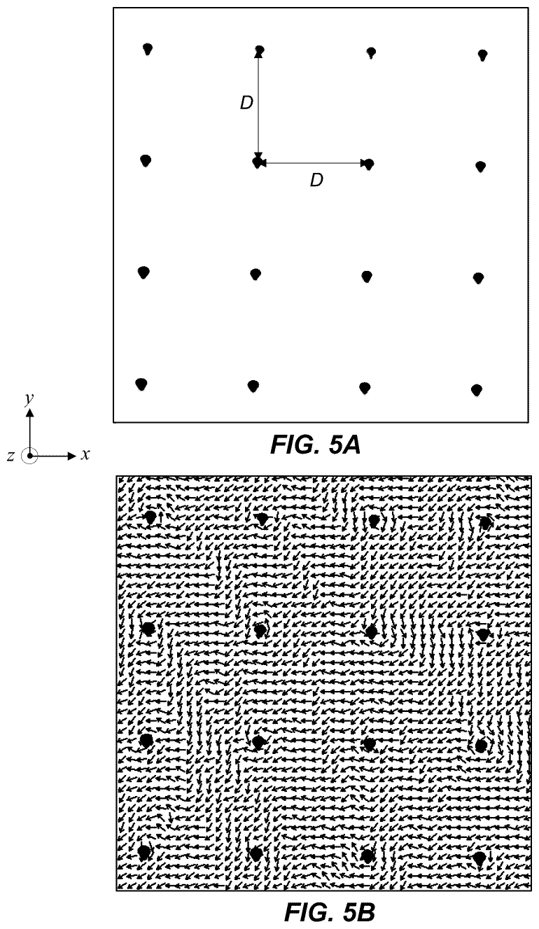

Of course, the deformations shown in FIGS. 4A-4E are schematic and for illustration purposes only; they are not necessarily to scale. Moreover, the required process steps will typically result in “imperfect” shapes, as illustrated in FIG. 5A. Still, the deformations obtained essentially remain point deformations.

Depending on the fabrication process used, the extent or degree of the deformations of the film 222b-e at the center of (or inside) the deformations may be more important than at the boundary. That is, the degree of deformation may decrease from the center of a deformation toward its periphery. For example, the extent of the recess at the center of a blind hole 225b-d is more important than at its periphery. A through-hole (see FIG. 4A) is an extreme case, where the degree of deformation goes from a maximum level (inside the hole) to a minimum (i.e., zero) deformation outside of the hole, i.e., at the boundary, that is, at the level of the undeformed film at the periphery of the hole.

### 1.1.3. Advantages

Remarkably, the point deformations 225 act as pinning sites for magnetic domains of the ferromagnetic film 222. They give rise to emergent behaviors, whereby dipolar/exchange couplings between neighboring nanomagnets result in a variety of complex, collective phenomena, which can be exploited for reservoir computing. More precisely, the ferromagnetic film 222 makes it possible to drive emergent behaviors directly by applying (or otherwise generating) magnetic fields or spin torques. A driving system 21 can be used to initialize the 2D array with an in-plane magnetic field pulse of strength Hₛₐₜ. The emergent behaviors are both driven and tuned by the applied field strength. For example, by applying a rotating magnetic field of appropriate amplitude, a magnetic state of the physical reservoir 22 is set, which shows an emergent behavior. This is caused by the point deformations (pinning sites); the interactions of domain walls across the lattice of deformations create emergent, non-linear variations of the array magnetization and domain wall population with the rotating field strength.

The point deformations 225 make it possible to obtain a robust and highly non-linear response of the ferromagnetic film 222 to external stimuli. Moreover, the 2D arrangement of point deformations gives rise to fading memory of the previous magnetization states. Thus, a ferromagnetic film 222 with a 2D arrangement of point deformations 225 as proposed herein has all the properties required to realize a physical reservoir for magnetic reservoir computing. Such a film can accordingly be used as a physical reservoir. For instance, data can be input by modulating the amplitude of a cyclic magnetic field and the reservoir response can be measured as a normalized domain wall population. In some embodiments, the reservoir response can also be measured as an overall magnetization component along a chosen axis.

To summarize, the point deformations 225 act as pinning sites for magnetic domains so that the physical reservoir 22 is nonlinear, stochastic (i.e., it reacts stochastically to an external stimulus), and displays fading memory. Moreover, as noted earlier, single-point deformations are much easier to obtain than nanorings. In addition, they require less power to set the state of the reservoir. For instance, the write field in antidot arrays typically ranges from 0.9 to 1.8 kA/m, which is a factor of 4 to 5 smaller than with corresponding ring arrays.

All this is now described in more detail, in reference to particular embodiments of the invention.

### 1.1.4. Preferred Embodiments

Punctures. As noted above, the point deformations 225 are preferably realized as punctures 225a-d, as illustrated in FIGS. 4A-4D. The punctures 225a-d may possibly include through holes and/or blind holes. In FIGS. 4A-4E, d denotes the average diameter of the point deformations, whereas D denotes the first neighbor distance.

Structural properties. In embodiments, the average first-neighbor distance D between the punctures 225 is between 0.2 μm and 5.0 μm. In some embodiments, and preferably, the average first-neighbor distance D between the punctures 225 is between 0.5 μm and 3.0 μm. In embodiments, the average diameter d of the punctures 225 is between 50 nm and 500 nm. In some embodiments, and preferably, the average diameter d of the punctures 225 is between 70 nm and 380 nm. Using such dimensions has advantages in terms of dip field, as discussed later in detail. The first-neighbor distances D between the punctures are measured parallel to the plane (x, y), that is, parallel to a main surface of the ferromagnetic film 222, i.e., in-plane with the ferromagnetic film 222. The diameters d of the punctures 225 are measured parallel to the main surface of the ferromagnetic film 222, too. Note, the average diameter d of the punctures is necessarily smaller than the average first-neighbor distance D, preferably at least twice smaller. The average first-neighbor distance D corresponds to the lattice constant (also called lattice step in the literature) when the 2D arrangement forms a square or hexagonal lattice.

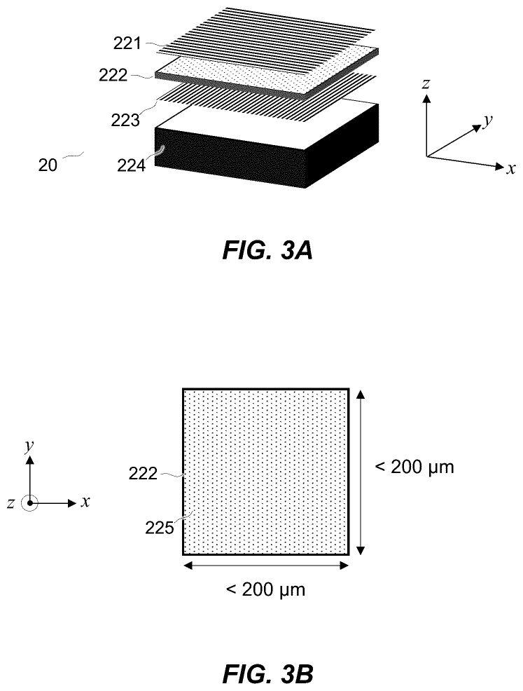

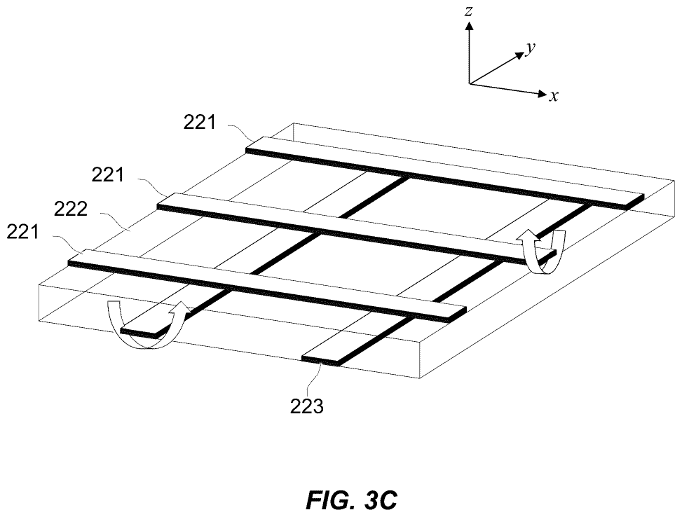

Lattice. As noted above, the 2D arrangement of point deformations 225 may form a lattice, such as a square lattice, as assumed in FIGS. 3A, 3B, 5A, and 5B. In some embodiments, the lattice may be an oblique, rectangular, or hexagonal lattice. For instance, is has been experimentally verified that a hexagonal lattice works, too. The lattice of point deformations 225 may, for example, be formed as an antidot lattice. Antidots are usually formed as through holes. The ferromagnetic film 222 may thus include a periodic array of through holes, which accordingly form a periodic array of pinning sites.

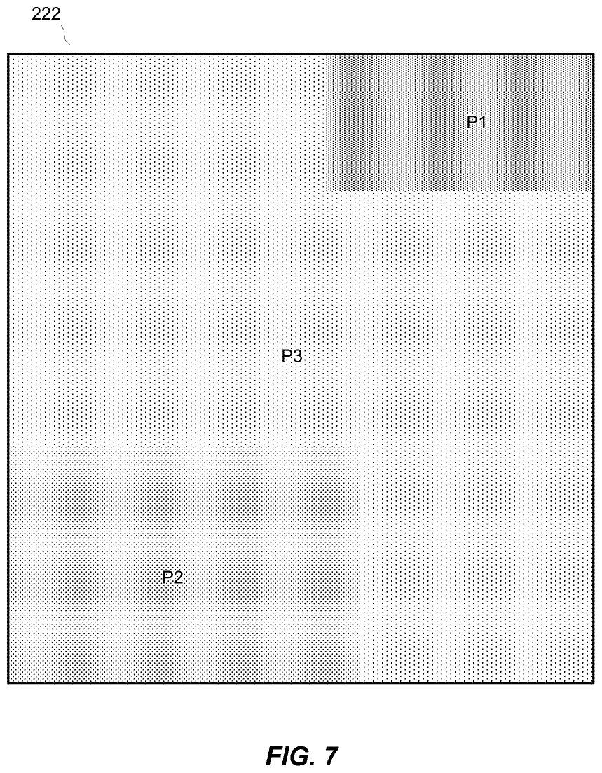

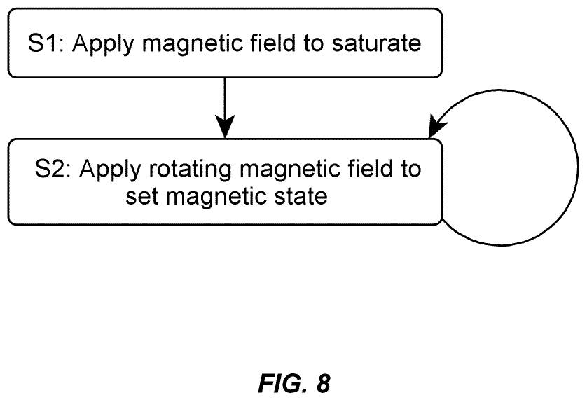

Lattice defects. In principle, the 2D arrangement of point deformations 225 may form at least two lattices of point deformations 225 in distinct areas of the ferromagnetic film 222, where the lattices have distinct lattice parameters. In the example of FIG. 7, the 2D arrangement of point deformations 225 form three distinct square lattices P1, P2, P3 in distinct areas of the ferromagnetic film 222. Varying the lattice constants across the film enhances the dynamics of the non-linear system formed by the ferromagnetic film 222. For the same reasons, the point deformations may form “crystallites” with different orientations (with same or different lattice constants). Moreover, point defects may be added. In some embodiments, the lattices may partly overlap at their boundaries.

Ferromagnetic materials. In embodiments, the ferromagnetic film 222 comprises one or more elements selected from the group consisting of transition metal elements. The ferromagnetic film 222 can notably be a pure metal, an alloy, or a compound, e.g., of iron, cobalt, nickel, and/or certain rare-earth metals. In some embodiments, and preferably, the ferromagnetic film 222 is composed of ferromagnets from the 3d-series in the periodic table (e.g., Fe, Co, Ni), in any composition. For example, the ferromagnetic film 222 may comprise FeₓNi₁₀₀₋ₓ, where 20≤x≤60. Examples of suitable compositions are Fe₅₅Ni₄₅ (i.e., x=55) and Fe₂₀N₁₈₀ (i.e., x=20). For example, the saturation magnetization Mₛ of the Fe₂₀N₁₈₀ permalloy is 800 kA/m; it changes with the film composition. The composition can be tuned to lower the saturation magnetization; a lower Mₛ value is preferable to achieve a low-power operation.

Nonmagnetic elements can be alloyed with these ferromagnets to tune magnetic properties, if necessary. For low-power devices, the material should be relatively soft (i.e., low coercive field H_{c}). Typical coercive fields measured on plain films are on the order of, or smaller than, 5 kA/m, although they usually are somewhat larger on patterned films because of domain wall pinning at the array of deformations. In magnetic reservoir computing, the complex emergent state forms because of wall pinning. It is characterized by a dip in the magnetic response vs. applied cycling magnetic field. The lower this “dip” field is, the lower is the energy required to set this state, which is key for designing low-power devices. In that respect, and as the inventors observed, using deformation dimensions and lattice step as described above reduces the dip field. For instance, for an array of antidots having an average diameter of 100 to 110 nm, the dip field levels off for lattice constants of 2 to 3 μm.

Film dimensions. The thickness of the ferromagnetic film 222 is typically between 2 nm and 50 nm. In some embodiments, and preferably, the thickness of the ferromagnetic film 222 is between 5 nm and 20 nm. Such thickness values are typically sufficient to allow emergent behaviors. Meanwhile, they make it easy to obtain punctures, whether by focused ion beam (FIB), nanoimprint, or nanostencil techniques. The ferromagnetic film 222 can, for instance, be deposited as a square or rectangle piece, where a length of each edge of the piece is of between 20 μm and 200 μm. For example, this length can be of 80 μm.

As seen in FIG. 3A, the physical reservoir 22 may further include a substrate 224 supporting the ferromagnetic film 222. The substrate provides a basis on which the ferromagnetic film 222 can be grown and patterned, thereby furthering the mechanical stability. The resulting layer structure can then be suitably arranged and connected in a magnetic reservoir computing apparatus, as described below in detail.

### 1.2. Magnetic Reservoir Computing Apparatus

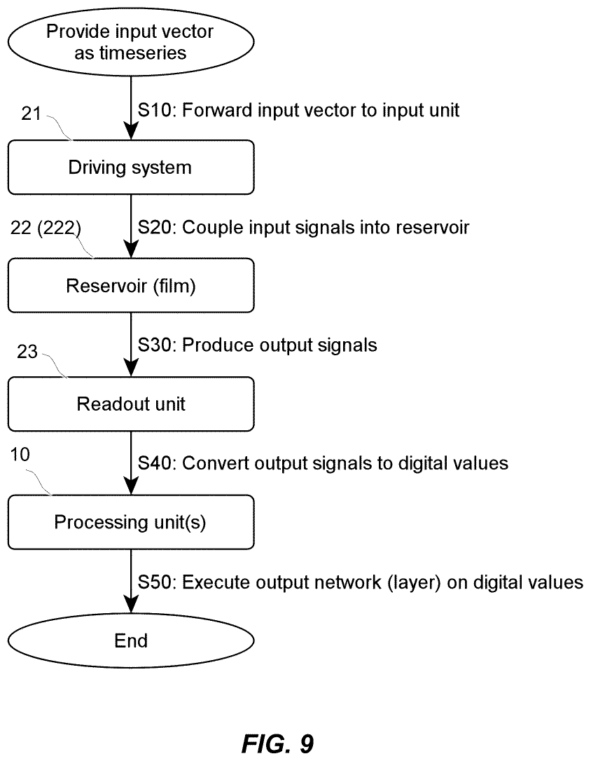

Referring to FIGS. 1A, 1B, and 9, another aspect of the invention is now described in detail, which concerns a magnetic reservoir computing apparatus 20 (or “apparatus” for short).

The apparatus 20 includes a physical reservoir 22, a driving system 21, and a readout unit 23. The physical reservoir 22 is a reservoir as described in section 1.1. That is, it essentially comprises a ferromagnetic film 222 with a 2D arrangement of point deformations 225, which are dimensioned to act as pinning sites for magnetic domains of the ferromagnetic film 222.

The driving system 21 is configured to magnetically saturate the ferromagnetic film 222 and couple input signals into the ferromagnetic film 222. That is, in operation, the driving system 21 is used to set a magnetic state of the ferromagnetic film 222. Note, setting the magnetic state of the reservoir means saturating the ferromagnetic film 222 and coupling signals into the reservoir. Thus, the driving system 21 includes all components required, on the one hand, to saturate the ferromagnetic film 222 and, on the other hand, to couple input signals into the reservoir.

The driving stimulus is the magnetic field. For example, coils can be used to saturate the ferromagnetic film 222 and then rotate the magnetic field to couple input signals (capturing input data) into the ferromagnetic film 222, as symbolically shown in FIG. 1B. Using coils to apply a magnetic field to a ferromagnetic film 222 is known by a person having ordinary skill in the art. In embodiments, the electronic signals (e.g., voltage amplitude levels) are mapped to magnetic field amplitudes, plus an offset, so that the magnetic fields fit the field range where the magnetic array responds best to produce a highly complex magnetic state.

The readout unit 23 is operatively connected to the physical reservoir 22 to read out output signals from the ferromagnetic film 222. The readout can, for instance, be done in three different ways. A first possibility is to perform optical readouts, by exploiting the magneto-optical Kerr effect, which leads to measure the overall magnetization component along an in-plane direction. A second possibility is to perform electrical readouts, whereby the anisotropic magnetoresistance (AMR) is measured, i.e., a signal that, loosely speaking, counts the domain walls. A third possibility is to use spin-polarized scanning electron microscopy (spin-SEM), a magnetic domain observation method, which images the local magnetization distribution. Note, the last possibility will typically not be a practical solution for most practical applications. However, it can be very useful to verify that domain walls indeed pin at the point deformations 225.

The readout unit 23 includes at least a readout circuitry, which collects signals from the physical reservoir 22, converts them to digital signals (if necessary), and forwards the resulting signals to an external processing unit 10, as in FIG. 1A. In some embodiments, the processing unit 10 forms part of the readout unit 23. In both cases, the processing unit 10 performs the final operations, i.e., it executes the output network (e.g., a single layer), using suitably trained weights wᵢ, as described later in detail. The processing unit 10 may itself be in data communication with a server 2, to which one or more users 4 may connect, e.g., via a personal computer (PC) 3, as assumed in FIG. 1A.

As noted above, the state of the physical reservoir 22 may notably be set using coils. That is, the driving system 21 may include two or more coils, which are configured to apply a rotating (macroscopic) magnetic field, as assumed in FIG. 1B. Such coils can thus be used to apply a rotating magnetic field, in-plane with the ferromagnetic film 222. This way, the driving system 21 is adapted to couple input signals into the physical reservoir 22. At least two coils are needed to generate a rotating field. Using coils to apply a rotating magnetic field, in-plane with a given material layer, is known by a person having ordinary skill in the art.

In principle, the driving system 21 may be configured to couple several parallel signals (corresponding to distinct input values) into various nodes of the reservoir network. For example, several input electrodes can be arranged on one side of the ferromagnetic film 222, whereby several signals can be coupled into the film though the input electrodes. Similarly, several output electrodes can be arranged on another side (e.g., opposite to said one side) of the ferromagnetic film 222, to read out output signals, e.g., by way of AMR measurements.

In some embodiments, in which a single input is preferred, the input values can be translated into a timeseries. Correspondingly, an input signal can be generated, which captures this timeseries. For example, the input timeseries can be translated into a time-dependent voltage signal Vᵢₙₚᵤₜ, as shown in FIG. 1A. In other words, input data can be applied in the form of time-dependent electric signals to the physical reservoir 22. This may for instance be achieved by modulating the amplitude of a rotating magnetic field, i.e., in accordance with H(t)=H₀+ΔH×Vᵢₙₚᵤₜ(t), where H(t) is the modulated field, H₀ is the field center, and AH is the modulation amplitude.

Eventually, the signal extracted from the physical reservoir 22 can be read as a voltage signal Vₒᵤₜₚᵤₜ(t), as also seen in FIG. 1A. Thus, a nonlinear transformation is achieved from the input signal captured by Vᵢₙₚᵤₜ(t) to the output signal Vₒᵤₜₚᵤₜ(t). Note, a smaller field center H₀ means that less energy is required for operation, which is preferable for a low-power operation of the reservoir. Conversely, larger values of AH gives rise to more available states. The fading memory timescale is determined by the magnetic pinning strength at the point deformations in the film and the input rate. Like Vᵢₙₚᵤₜ(t), the output signal Vₒᵤₜₚᵤₜ(t) encodes multiple values, which can be interpreted to form multiple signals corresponding to respective values. I.e., the multiple signals formed can be converted to digital values, if necessary. Such values or signals are then run through an output network, which is executed by the processing unit 10, as discussed below in detail.

In variants to coils applying a rotating magnetic field, the state of the ferromagnetic film 222 can be set by applying electrical currents. In this case, the driving system 21 is operatively connected to the ferromagnetic film 222 to apply one or more electric current signals to the ferromagnetic film 222. The current signals can either be applied locally or globally to the ferromagnetic film 222. In particular, one may locally generate magnetic fields thanks to conductors, e.g., current-carrying lines as used in standard magnetoresistive random-access memory (MRAM) devices, as assumed in FIGS. 3A and 3C. For example, the physical reservoir 22 may further include an arrangement of electrical conductors 221, 223 connecting the driving system 21 to multiple locations in the ferromagnetic film 222, as shown in FIG. 3C. In this case, the driving system 21 is configured to apply electric current signals to the ferromagnetic film 222, through the electrical conductors 221, 223, to locally generate magnetic fields in the ferromagnetic film 222, in-plane with the ferromagnetic film 222.

Another possibility is to use a spin torque mechanism to move domain walls. Such a spin torque mechanism may either rely on a spin-transfer torque or a spin-orbit torque effect, as known by a person having ordinary skill in the art. Thus, in embodiments, the driving system 21 is operatively connected to apply electric current signals to the ferromagnetic film 222, with a view to moving domain walls in the ferromagnetic film 222 according to a spin-transfer torque mechanism or a spin-orbit torque mechanism, which mechanisms respectively rely on the spin-transfer torque effect and the spin-orbit torque effect, as also known by a person having ordinary skill in the art.

As noted above, the magnetic reservoir computing apparatus 20 may further include a processing unit 10, which is connected to, or forms part of, the readout unit 23. The processing unit 10 may include one or more conventional processors. It may possibly form part of a conventional computer or a server 2, itself in data communication with one or more user computers 3. It may also be a non-conventional processing unit, as exemplified below. In all cases, the processing unit 10 is configured to further process signals (or values corresponding to such signals) obtained from the physical reservoir 22 through the readout unit 23. In particular, the processing unit 10 may be configured to execute an output network based on such values or signals, where the output network includes at least one output layer. Once the parameters of the output network have been learned, the output network can be used to perform inferences based on the signals or values obtained from the physical reservoir 22.

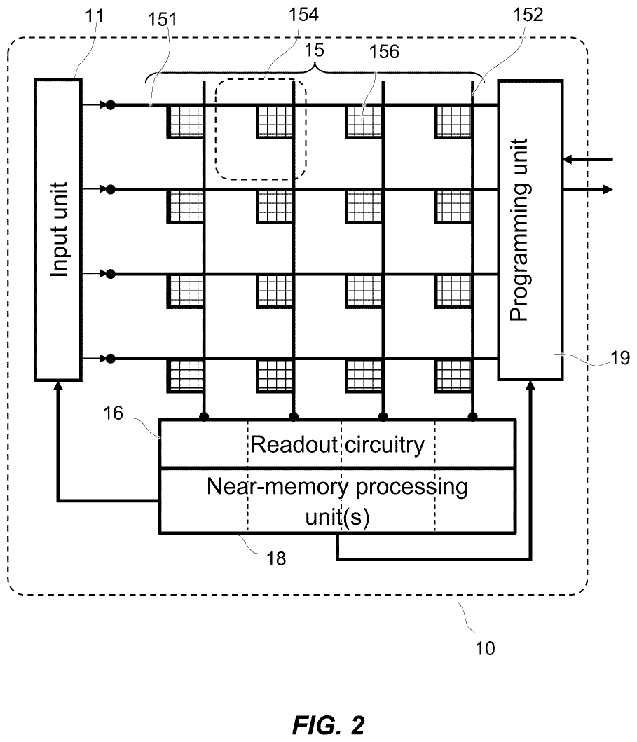

Assume that the output network consists of a single output layer, for simplicity. In this case, a linear operation is required, i.e., a vector-matrix operation, given that the read-out signal is converted into distinct signals (or corresponding values). Thus, in some embodiments, the processor unit can advantageously be an in-memory compute (IMC) unit 10 having a crossbar array structure 15, as shown in FIG. 2. Such a crossbar array implements one neural layer at a time and can thus advantageously be used at the output of the reservoir. The IMC unit 10 may itself include a digital processing unit 18, e.g., configured as a near-memory compute unit. This processing unit 10 may be co-integrated with other components of the apparatus 20. The IMC unit 10 of FIG. 2 is described in detail in section 2. In some embodiments, several IMC units 10 are cascaded, to implement several output neural layers, if necessary.

### 1.3. Method of Operating a Reservoir Computing Apparatus

A further aspect of the invention is now described in reference to FIGS. 8 and 9. This aspect concerns a method of operating a reservoir computing apparatus 20 such as described in section 1.2. A key feature of this method is to suitably set at steps S1, S2 a magnetic state of the physical reservoir 22, as illustrated in FIG. 8. The magnetic state is set by first saturating, at step S1, the ferromagnetic film 222 and then coupling input signals into the physical reservoir 22, which results in the generation, at step S2, of one or more magnetic fields, in-plane with the ferromagnetic film 222. That is, the ferromagnetic film 222 first needs to be saturated (magnetically), before modulating a magnetic field to set the state of the reservoir, as indicated in FIG. 8. The state of the reservoir can be set by a driving system 21 as described in the previous section.

As also noted earlier, signals can be coupled into the physical reservoir 22 by converting electric signals to a reasonably adjusted magnetic field, which then moves domain walls such that a complex magnetic pattern is emerging. Alternatively, instead of magnetic fields, spin torques can be used. In this case, one converts the input electric signals to a reasonably adjusted current, which moves domain walls. In all cases, coupling signals into the physical reservoir 22 results in setting a complex magnetic state in the ferromagnetic film 222.

Note, perpendicularly magnetized ferromagnets can also be an option, as long as the perpendicular anisotropy remains relatively modest. In such a case, rotational magnetic fields would cycle from out-of-plane to in-plane and back. Note, even with this change of coordinate system, the concept of setting a complex magnetic state for use in reservoir computing remains fundamentally unchanged.

As further seen in FIG. 9, after coupling, at step S20, input signals into the physical reservoir 22, the method may comprise reading out, at step S40, output signals from the physical reservoir 22 and further processing, at step S50, such signals to obtain one or more inference results, as discussed in section 1.2. Note, the output signals are here assumed to be processed for inferencing purposes. For training purposes, signals are similarly processed on the forward pass. In addition, weight gradients are computed during a backward pass to adjust the weights.

To summarize: injecting signals in the physical reservoir 22 causes the physical reservoir 22 to produce, at step S30, response signals. The response signals produced by the physical reservoir 22 are read out, at step S40, by the readout unit 23. The readout signals can then be injected (if necessary, after conversion to digital values) into a processing unit 10, which runs, at step S50, a simple network in output, whether for training or inferencing purposes.

### 1.4. Fabrication Methods

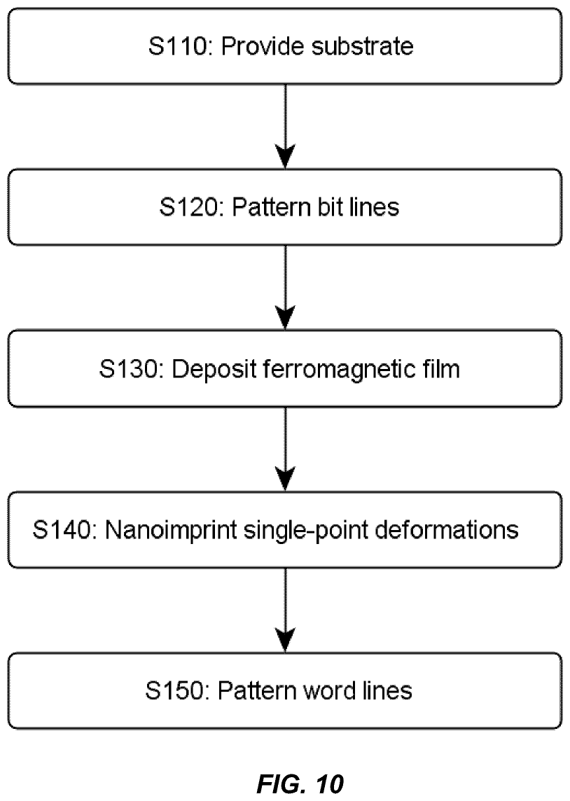

Referring now to FIG. 10, a final aspect of the invention is described, which concerns methods of fabricating a reservoir computing apparatus 20. The present fabrication methods revolve around patterning, at step S140, a ferromagnetic film 222 to obtain a 2D arrangement of point deformations 225 in the ferromagnetic film 222. Consistently with previous aspects of the invention, the point deformations 225 must be dimensioned to act as pinning sites for magnetic domains of the ferromagnetic film 222. This makes it possible to obtain a physical reservoir 22, which contains the ferromagnetic film 222. Eventually, the physical reservoir 22 is connected with one or more additional components, to obtain a reservoir computing apparatus 20.

In embodiments, the ferromagnetic film 222 is patterned, at step S140, by nanoimprint lithography. Nanoimprint lithography is known by a person having ordinary skill in the art; it is a low-cost, high throughput, and high-resolution nanolithography process, which creates patterns by mechanical deformation. For example, use can be made of a microscopic rubber stamp. In some embodiments, the ferromagnetic film 222 is patterned, at step S140, using a nanostencil technique, i.e., a lithography-free process using evaporation through a shadow mask. For example, a dot lattice can be fabricated using a nanostencil technique. An antidot lattice can be fabricated with shadow masks, too. For example, a lattice of depressions can be achieved using a shadow mask by tuning the distance between the mask and the substrate. Nanoimprint lithography and nanostencil techniques are low-cost techniques, which result in a resolution that is sufficient for the present purposes. Still, other techniques can be contemplated, such as focused-ion beam (FIB) techniques. FIB techniques allow flexibility in the choice of the arrangement, diameter, and first-neighbor distances between the point deformations.

The above embodiments have been succinctly described in reference to the accompanying drawings and may accommodate a number of variants. Several combinations of the above features may be contemplated. Examples are given in the next section.

### 2. Detailed Description of the Appended Drawings

FIG. 1A is a diagram illustrating components 10, 21, 22, 23 of a reservoir computing apparatus 20 according to embodiments. FIG. 1B is a high-level diagram of the same apparatus, which illustrates connections between components 2, 3, 10, 21, 222, 23 of the apparatus. In this example, the driving system 21 of the apparatus includes two coils, which are used to set the state of the physical reservoir 22. In detail, a user 4 interacts with a server 2, through a PC 3, in order to instruct to perform inferences based on a reservoir computing network. Input data (e.g., a vector x having vector components x₁, x₂, x₃, x₄) are loaded in the driving system 21. Such input data may possibly have been obtained from initial user data, using feature extraction and dimension reduction, as usual in the art. The driving system 21 first converts such input data into a timeseries, which is captured in the form of a time-dependent electrical signal. The latter is coupled into the physical reservoir 22 (embodying a reservoir network), causing the reservoir to non-linearly respond. The physical reservoir 22 includes a ferromagnetic film 222 (not visible in FIG. 1A) such as shown in FIGS. 3A-4E. This ferromagnetic film 222 is assumed to have been previously saturated (step S1 in FIG. 8). The readout unit 23 reads out the response signal, converts it to output signals, and feeds such signals into a processing unit 10. The latter runs an output neural layer on such signals to produce a classification result (a binary classification in this example), which is returned to the server 2 and then to the user PC 3.

FIG. 2 is a diagram of an IMC unit 10 having a crossbar array structure 15, which can be used in output of a reservoir computing apparatus 20 as shown in FIGS. 1A and 2A. The IMC unit 10 includes N input lines 151 and M output lines 152, which lines are interconnected at cross-points (i.e., junctions). The cross-points accordingly define N×M cells 154, also called unit cells. The input and output lines are interconnected via memory systems 156. The IMC unit 10 contains at least two input lines and at least two output lines (i.e., N≥2 and M≥2). In practice, the number of active input lines 151 and active output lines 152 will depend on the dimensionality of the problem to be solved. That is, the number N′ of active input lines (N′≤N) corresponds to the number of signals (or values) obtained from the reservoir network, while the number M′ of active output lines (M′≤M) corresponds to the number of outputs required to perform the desired inference (i.e., classifications or prediction). Each IMC unit 10 implements up to M neurons at a time.

The memory elements may be digital memory devices. In that case, the signals read out from the reservoir need first be converted to digital values. In some embodiments, the memory elements are analog memory devices, which can notably be phase-change memory (PCM) devices, resistive random-access memory (RRAM) devices, or flash memory cell devices. Using such devices, a weight value is mapped over a conductance range of a single memory element. By contrast, multiple binary devices representing different weight bits would be used for digital operations.

Using analog memory devices, input vectors (corresponding to signals output from the reservoir) are encoded as signals applied by the input unit 11 to the input lines 151 of the crossbar array to perform multiply-accumulate (MAC) operations. The coefficients of the matrix (“weights”) are stored in columns of cells. Next to every column of cells is a column of arithmetic units (not shown) that multiplies the weights with input vector values (creating partial products) and finally accumulates all partial products to produce the outcome of a full dot-product. Such an architecture can simply and efficiently map a vector-matrix multiplication. The weights can be updated by reprogramming the memory elements 156, thanks to a programming unit 19. Such an approach breaks the “memory wall” as it fuses the arithmetic- and memory unit into a single IMC unit. What is more, using analog memory devices in an IMC unit allows MVM operations to be efficiently performed, by exploiting analog storage capability of the IMC device and Kirchhoff's circuits laws.

The IMC unit 10 includes a readout circuit 16 connected in output of the output lines 152. The programming unit 19 may thus be connected to the readout circuit 16, in output thereof, so as to be able to adjust conductance values of the memory elements in accordance with, e.g., a single-device programming method. Moreover, the IMC unit 10 may further include a processing unit 18, connected in output of the IMC unit 10, i.e., in output of the readout circuitry 16. This processing unit 18 is preferably arranged as a near-memory processing unit. In that case, the programming unit 19 may advantageously be connected in output of the near-memory processing unit 18, to allow a closed-loop programming of the crossbar array structure 15, as assumed in FIG. 2. In some embodiments, the processing unit 18 and the programming unit 19 are implemented as a single unit. The programming unit 19 may further include an input/output (I/O) controller and be configured to communicate with external devices or computers 2, 3, as illustrated in FIG. 1A. The processing unit 18 can notably be used to apply activation functions and perform a classification, e.g., a binary classification (class #1, class #2), as assumed in FIG. 1A.

FIG. 3A is an exploded view of a layer structure of a physical reservoir 22, involving a ferromagnetic film 222. The ferromagnetic film 222 is patterned, so as to show a 2D arrangement of punctures. FIG. 3B shows a corresponding top view. Electrical conductors 221, 223 are further patterned on each side of the ferromagnetic film 222, in the form of current-carrying lines as used in standard MRAM devices, as also seen in the 3D view of FIG. 3C. The layer stack is formed on a substrate 224 (e.g., copper).

FIGS. 4A-4E are 2D cross-sectional views of a portion of a ferromagnetic film 222a-e of a physical reservoir, which schematically illustrate how the ferromagnetic film can be locally processed to form point deformations 225a-e. In each case, the point deformations 225a-e are dimensioned to act as pinning sites for magnetic domains of the ferromagnetic film 222. In the examples of FIGS. 4A-4E, the point deformations 225a-d are formed as punctures, whereas they are formed as protrusions 225e in the example of FIG. 4E. The quantity d denotes the average diameter of the point deformations, whereas D denotes the first neighbor distance.

FIG. 5A is a map of secondary electrons of a permalloy Fe₅₅Ni₄₅ antidot lattice fabricated using a FIB tool on a Si(001) substrate. FIG. 5B shows the corresponding in-plane magnetization distribution in which the magnetization direction is represented by arrows. A thresholding function was applied to the topographic map of FIG. 5A, for the sake of depiction. The black spots in FIG. 5A correspond to antidots (i.e., missing portions of permalloy in the 10 nm thick permalloy layer), the actual diameters of which is about 100 nm, with a distance between the antidots of 2 μm. FIG. 5B shows how magnetic domains pin at the antidot locations. Note, ten rotational magnetic field cycles have been applied to the film prior to image acquisition in this example. The black dots correspond to the positions of the antidots, as determined from FIG. 5A. The image size is 7.3 μm×7.3 μm.

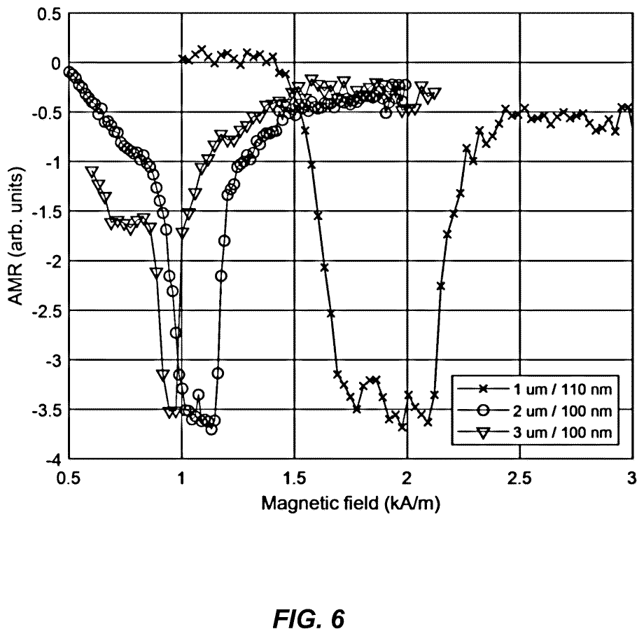

FIG. 6 is a graph representing the anisotropic magnetoresistance (AMR) of a ferromagnetic film (Fe₅₅Ni₄₅) having a thickness of 10 nm as a function of the applied magnetic field. The graph illustrates the overall magnetic response to a cycling magnetic field, for various lattice constants (1, 2, and 3 μm) and dot diameters of 100/110 μm. Not all results are depicted, for clarity. In the actual experiment, the antidot lattice constant (i.e., the distance between holes “drilled” into the magnetic film), was varied from 0.5 to 3.0 μm, and the antidot diameters, were varied from 70 to 380 nm. One may consider the field at which the overall magnetic response to the cycling magnetic field was the smallest (the “dip” field) as a relevant figure of merit. At and near this field, the complex emergent state is formed that is being used for reservoir computing purposes; the lower this field, the lower the energy required to set this state. The present inventors observed that, for a constant antidot diameter, the dip field is being reduced for larger lattice constant, but levels off at 2 to 3 μm.

FIG. 7 schematically represent a top view of a ferromagnetic film 222 similar to that of FIG. 3B, except that the film of FIG. 7 includes three distinct lattices of punctures in respective distinct areas of the film. The three lattices having distinct lattice constants.

FIGS. 8 and 9 are flowcharts illustrating high-level steps of a method of operating a reservoir computing apparatus 20 such as shown in FIGS. 1A and 1B. The method comprises setting the magnetic state of the ferromagnetic film 222 by first saturating, at step S1, the ferromagnetic film 222 and then coupling, at step S2, input signals into the physical reservoir 22, which results in the generation of in-plane magnetic fields, see FIG. 8. Step S2 is repeated as needed to repeatedly couple various input signals into the physical reservoir 22. A full sequence of operations is shown in FIG. 9; the ferromagnetic film 222 is assumed to have already been saturated. An input vector is forwarded, at step S10, to the driving system 21, which converts the vector into a timeseries and encodes the timeseries as a time-dependent, electric input signal. This signal is then applied, at step S20, i.e., coupled into, the physical reservoir 22. The latter accordingly generates, at step S30, a response signal, which is read out, at step S40, by the readout unit 23. In this example, the readout unit 23 converts the read-out signals into digital values, which are then fed to a conventional computing device 2, 3 for it to run, at step S50, a neural network (e.g., a mere output layer) on such values, and obtain an inference result. In some embodiments, the readout unit 23 converts the read-out signals into input signals that are fed to an IMC unit 10 such as shown in FIG. 2, and as explained above.

FIG. 10 is a flowchart illustrating high-level steps of a method of fabricating a ferromagnetic film 222 of a physical reservoir 22 as shown in FIG. 3A. A substrate is provided at step S110. Bit lines 223 are patterned at step S120, prior to depositing, at step S130, the ferromagnetic film 222. The latter is then patterned, at step S140, using nanoimprint lithography, to obtain the point deformations 225. The words lines are then patterned at step S150. The physical reservoir 22 is finally assembled in the apparatus 20. For practical applications, the substrate will typically include silicon, as well as some thin additional layers on top of the silicon layer.

According to one embodiment of the present invention, a physical reservoir for a magnetic reservoir computing apparatus is provided. The physical reservoir includes a ferromagnetic film with a two-dimensional arrangement of point deformations dimensioned to act as pinning sites for magnetic domains of the ferromagnetic film.

In an embodiment, the point deformations of the physical reservoir are punctures.

In an embodiment, an average first-neighbor distance between the punctures is between 0.2 μm and 5.0 μm, wherein any first-neighbor distance between the punctures is measured parallel to a main surface of the ferromagnetic film, and an average diameter of the punctures is between 50 nm and 500 nm, wherein any diameter of the punctures is measured parallel to the main surface of the ferromagnetic film, and further wherein the average diameter of the punctures is smaller than the average first-neighbor distance.

In an embodiment, the average first-neighbor distance between the punctures is between 0.5 μm and 3.0 μm, and the average diameter of the punctures is between 70 nm and 380 nm.

In an embodiment, a thickness of the ferromagnetic film is between 2 nm and 50 nm.

In an embodiment, a thickness of the ferromagnetic film is between 5 nm and 20 nm.

In an embodiment, the two-dimensional arrangement forms at least one lattice of the point deformations.

In an embodiment, the at least one lattice includes an antidot lattice.

In an embodiment, the at least one lattice includes a square lattice.

In an embodiment, the two-dimensional arrangement forms at least two lattices of point deformations, wherein the at least two lattices have distinct lattice parameters, in distinct areas of the ferromagnetic film.

In an embodiment, the ferromagnetic film includes one or more elements selected from the group consisting of transition metal elements.

In an embodiment, the ferromagnetic film comprises FeₓNi₁₀₀₋ₓ, where 20≤x≤60.

In an embodiment, a length of each edge of the ferromagnetic film is of between 20 μm and 200 μm.

In an embodiment, the physical reservoir further includes a substrate supporting the ferromagnetic film.

According to another embodiment of the present invention, a magnetic reservoir apparatus is provided. The magnetic reservoir computing apparatus includes a physical reservoir, wherein the physical reservoir includes a ferromagnetic film with a two-dimensional arrangement of point deformations dimensioned to act as pinning sites for magnetic domains of the ferromagnetic film. The magnetic reservoir computing apparatus further includes a driving system configured to saturate the ferromagnetic film and couple input signals into the ferromagnetic film to set a magnetic state of the ferromagnetic film. The magnetic reservoir computing apparatus further includes a readout unit that is operatively connected to the physical reservoir to read out output signals from the ferromagnetic film.

In an embodiment, the driving system includes two or more coils configured to apply a rotating magnetic field, in-plane with the ferromagnetic film, wherein the driving system is adapted to couple input signals into the physical reservoir.

In an embodiment, the driving system is operatively connected to the ferromagnetic film to apply one or more electric current signals to the ferromagnetic film.

In an embodiment, the physical reservoir includes an arrangement of electrical conductors connecting the driving system to multiple locations in the ferromagnetic film, wherein the driving system is configured to apply electric current signals to the ferromagnetic film, through the electrical conductors, to locally generate magnetic fields in the ferromagnetic film, in-plane with the ferromagnetic film.

In an embodiment, the driving system is operatively connected to apply the electric current signals to the ferromagnetic film to move domain walls in the ferromagnetic film according to one of a spin-transfer torque mechanism and a spin-orbit torque mechanism.

In an embodiment, the magnetic reservoir computing apparatus further includes a processing unit connected to the readout unit and configured to further process signals from the physical reservoir.

According to another embodiment of the present invention, a method of operating a reservoir computing apparatus is provided. The method includes setting a magnetic state of a physical reservoir, wherein the physical reservoir comprises a ferromagnetic film with a two-dimensional arrangement of point deformations dimensioned to act as pinning sites for magnetic domains of the ferromagnetic film, and wherein the magnetic state is set by saturating the ferromagnetic film and coupling input signals into the physical reservoir to generate one or more magnetic fields in-plane with the ferromagnetic film.

In an embodiment, the method further includes reading out output signals from the physical reservoir, and processing the output signals to obtain one or more inference results.

According to yet another embodiment of the present invention, a method of fabricating a reservoir computing apparatus is provided. The method includes patterning a ferromagnetic film to obtain a two-dimensional arrangement of point deformations in the ferromagnetic film, wherein the point deformations are dimensioned to act as pinning sites for magnetic domains of the ferromagnetic film to thereby obtain a physical reservoir containing the ferromagnetic film. The method further includes connecting the physical reservoir with one or more additional components of the reservoir computing apparatus.

In an embodiment, the ferromagnetic film is patterned by nanoimprint lithography.

In an embodiment, the ferromagnetic film is patterned using a nanostencil technique.

While the present invention has been described with reference to a limited number of embodiments, variants, and the accompanying drawings, it will be understood by those skilled in the art that various changes may be made, and equivalents may be substituted without departing from the scope of the present invention. In particular, a feature (device-like or method-like) recited in a given embodiment, variant or shown in a drawing may be combined with or replace another feature in another embodiment, variant or drawing, without departing from the scope of the present invention. Various combinations of the features described in respect of any of the above embodiments or variants may accordingly be contemplated, that remain within the scope of the appended claims. In addition, many minor modifications may be made to adapt a particular situation or material to the teachings of the present invention without departing from its scope. Therefore, it is intended that the present invention is not limited to the particular embodiments disclosed, but that the present invention will include all embodiments falling within the scope of the appended claims. In addition, many other variants than explicitly touched above can be contemplated.

What is claimed is:

1. A physical reservoir for a magnetic reservoir computing apparatus, wherein the physical reservoir includes a ferromagnetic film with a two-dimensional arrangement of point deformations dimensioned to act as pinning sites for magnetic domains of the ferromagnetic film.

2. The physical reservoir according to claim 1, wherein the point deformations are punctures.

3. The physical reservoir according to claim 2, wherein:
an average first-neighbor distance between the punctures is between 0.2 μm and 5.0 μm, wherein any first-neighbor distance between the punctures is measured parallel to a main surface of the ferromagnetic film; and
an average diameter of the punctures is between 50 nm and 500 nm, wherein any diameter of the punctures is measured parallel to the main surface of the ferromagnetic film, and further wherein the average diameter of the punctures is smaller than the average first-neighbor distance.

4. The physical reservoir according to claim 3, wherein:
the average first-neighbor distance between the punctures is between 0.5 μm and 3.0 μm; and
the average diameter of the punctures is between 70 nm and 380 nm.

5. The physical reservoir according to claim 3, wherein a thickness of the ferromagnetic film is between 2 nm and 50 nm.

6. The physical reservoir according to claim 5, wherein the thickness of the ferromagnetic film is of between 5 nm and 20 nm.

7. The physical reservoir according to claim 1, wherein the two-dimensional arrangement forms at least one lattice of the point deformations.

8. The physical reservoir according to claim 7, wherein the at least one lattice includes an antidot lattice.

9. The physical reservoir according to claim 7, wherein the at least one lattice includes a square lattice.

10. The physical reservoir according to claim 1, wherein the two-dimensional arrangement forms at least two lattices of point deformations, and wherein the at least two lattices of point deformations have distinct lattice parameters, in distinct areas of the ferromagnetic film.

11. The physical reservoir according to claim 1, wherein the ferromagnetic film comprises one or more elements selected from the group consisting of transition metal elements.

12. The physical reservoir according to claim 11, wherein the ferromagnetic film comprises FeₓNi₁₀₀₋ₓ, where 20≤x≤60.

13. The physical reservoir according to claim 1, wherein a length of each edge of the ferromagnetic film is between 20 μm and 200 μm.

14. The physical reservoir according to claim 1, wherein the physical reservoir further includes a substrate supporting the ferromagnetic film.

15. A magnetic reservoir computing apparatus comprising:
a physical reservoir, wherein the physical reservoir comprises a ferromagnetic film with a two-dimensional arrangement of point deformations dimensioned to act as pinning sites for magnetic domains of the ferromagnetic film;
a driving system configured to saturate the ferromagnetic film and couple input signals into the ferromagnetic film to set a magnetic state of the ferromagnetic film; and
a readout unit operatively connected to the physical reservoir to read out output signals from the ferromagnetic film.

16. The magnetic reservoir computing apparatus according to claim 15, wherein the driving system includes two or more coils configured to apply a rotating magnetic field, in-plane with the ferromagnetic film, and wherein the driving system is adapted to couple input signals into the physical reservoir.

17. The magnetic reservoir computing apparatus according to claim 15, wherein the driving system is operatively connected to the ferromagnetic film to apply one or more electric current signals to the ferromagnetic film.

18. The magnetic reservoir computing apparatus according to claim 17, wherein:
the physical reservoir includes an arrangement of electrical conductors connecting the driving system to multiple locations in the ferromagnetic film; and
the driving system is configured to apply electric current signals to the ferromagnetic film, through the electrical conductors, to locally generate magnetic fields in the ferromagnetic film, in-plane with the ferromagnetic film.

19. The magnetic reservoir computing apparatus according to claim 18, wherein the driving system is operatively connected to apply the electric current signals to the ferromagnetic film to move domain walls in the ferromagnetic film according to one of a spin-transfer torque mechanism and a spin-orbit torque mechanism.

20. The magnetic reservoir computing apparatus according to claim 15, further comprising a processing unit connected to the readout unit and configured to further process signals from the reservoir.

21. A method of operating a reservoir computing apparatus, the method comprising:
setting a magnetic state of the physical reservoir, wherein the physical reservoir comprises a ferromagnetic film with a two-dimensional arrangement of point deformations dimensioned to act as pinning sites for magnetic domains of the ferromagnetic film, and wherein the magnetic state is set by:
saturating the ferromagnetic film; and
coupling input signals into the physical reservoir to generate one or more magnetic fields in-plane with the ferromagnetic film.

22. The method according to claim 21, further comprising:
reading out output signals from the physical reservoir; and
processing the output signals to obtain one or more inference results.

23. A method of fabricating a reservoir computing apparatus, the method comprising:
patterning a ferromagnetic film to obtain a two-dimensional arrangement of point deformations in the ferromagnetic film, wherein the point deformations are dimensioned to act as pinning sites for magnetic domains of the ferromagnetic film to obtain a physical reservoir containing the ferromagnetic film; and
connecting the physical reservoir with one or more additional components of the reservoir computing apparatus.

24. The method according to claim 23, wherein the ferromagnetic film is patterned by nanoimprint lithography.

25. The method according to claim 23, wherein the ferromagnetic film is patterned using a nanostencil technique.
